(19) United States
(12) Patent Application Publication
(10) Pub. No.: US 2012/0193772 A1
(43) Pub. Date: Aug. 2, 2012

(54) STACKED DIE PACKAGES WITH FLIP-CHIP AND WIRE BONDING DIES

(76) Inventor: Hunt Hang Jiang, Saratoga, CA (US)

(21) Appl. No.: 13/016,661

(22) Filed: Jan. 28, 2011

(51) Int. Cl. H01L 25/07

(52) U.S. Cl. 257/666; 257/E25.018

(57) ABSTRACT

The present technology discloses a stacked die package. In one embodiment, a package comprises a first die, a second die, and a leadframe. The first die is electrically coupled to the bottom surface of the leadframe through contact bump/bumps. The second die is electrically coupled to the top surface of the leadframe through wirebond/wires. The second die is mounted on the top surface of the first die.

### TECHNICAL FIELD

The present technology generally relates to semiconductor packages, and more particularly relates to stacked die packages incorporating a flip-chip die and a wire bonding die.

### BACKGROUND

The requirements for custom electronics products have increased significantly in recent years. Miniaturization and portability are overwhelming trends which push the integrated circuit (“IC”) package to be more compact. Accordingly, portable electronic devices become smaller each day along with more functions. Thus, today's power supply systems are required to have smaller sizes along with higher power output, more functions and better efficiencies. Under these requirements, multi-chip packages are presently adopted in power supply applications. Typically, a multi-chip package includes a discrete power die and a controller die in a single package to achieve better control and smaller size. Stacked die packages are one type of multi-chip packages which stack multiple dies vertically in the same package to offer multiple functionality, smaller footprints and lower profiles along with lower cost.

FIG. 1A shows a typical stacked die package 100 according to the prior art. The package 100 includes a first die 11 such as a power supply die and a second IC die 12 such as a controller die. The first die 11 with a larger size is attached on a die attach paddle 101 of the lead frame 10 through a die attach adhesive 141. The second die 12 with a smaller size is attached on an active surface of the first die 11 through an adhesive 142 while the electrical pads 110 on the first die 11 are exposed at the periphery of the first die 11. Bonding wires 111, 121 connect the pads 110 and 120 on the first die 11 and the second die 12 to the leads of the leadframe 10, respectively.

As shown in FIG. 1B, both the first and second dies 11 and 12 are inside the window 102 of the leadframe 10. This requirement limits further reduction of the package size. Moreover, for power supply applications, a die with high power discrete devices fabricated thereon requires high current carrying ability and low resistance for interconnections. Bonding wires are not power-saving enough due to their small diameters and relatively long lengths. Also, if the first and second dies 11 and 12 are not thin enough, the die attach paddle 101 must be offset from the leads of the leadframe 10, complicating the manufacturing process.

### BRIEF DESCRIPTION OF THE DRAWINGS

FIG. 1A is a cross-sectional view of a conventional stacked die package 100 according to the prior art.

FIG. 1B is a plan view of the package 100 in FIG. 1A.

FIG. 2 is a cross-sectional view of a stacked die package 200 according to embodiments of the present technology.

FIG. 3A is a plan view 300 of the stacked die package in FIG. 2.

FIG. 3B is a perspective view of the package 300 in FIG. 2.

FIG. 4 is a cross-sectional view of a stacked die package 400 according to additional embodiments of the present technology.

FIG. 5 is a perspective view of a stacked die package 500 according to further embodiments of the present technology.

FIG. 6 is a perspective view of a stacked die package 600 according to yet further embodiments of the present technology.

FIG. 7 is a perspective view of another stacked die package 700 according to embodiments of the present technology.

FIG. 8A is a schematic circuit diagram showing a synchronous rectification circuit 8, and FIG. 8B is a plan view of a stacked die package 800B of the synchronous rectifier module 800 according to additional embodiments of the present technology.

FIG. 9A is a schematic circuit diagram showing a buck converter 9, and

FIG. 9B is a plan view of a package 900B of the converter module 900 according to further embodiments of the present technology.

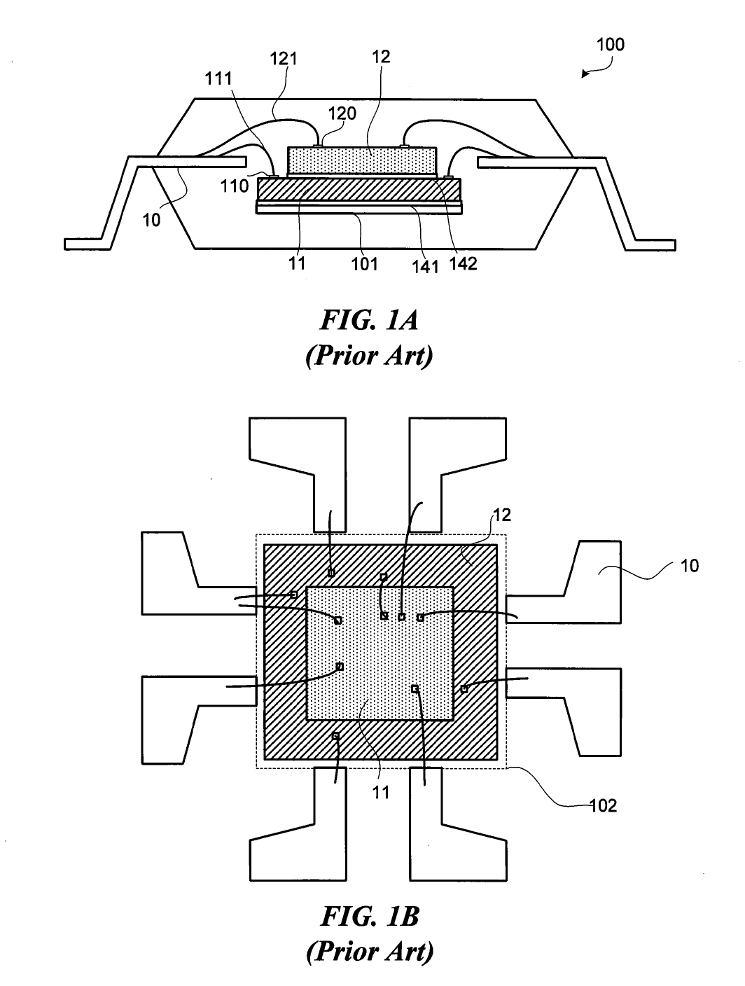

### DETAILED DESCRIPTION

The present technology is directed to stacked die packages incorporating flip-chip dies and wire bonding dies. The term “flip-chip die” generally refers to a semiconductor chip having contacts directly connected to a leadframe and/or other suitable package substrates by solder bumps, gold bump, and/or other suitable contact bumps. The term “wire bonding die” generally refers to a semiconductor chip having a contact connected to a leadframe and/or other suitable package substrates by a wirebond. The term “contact bump” generally refers to a conductive material in a ball or a pillar shape used to directly connect two contact areas.

In one embodiment, the present technology is directed to a stacked die package that includes a leadframe, a first die, and a second die. The leadframe has a plurality of leads. The first die has a plurality of contact bumps at a first surface and a second surface opposite of the first surface. The first die is electrically coupled to a bottom surface of the leadframe through contact bumps. The second die has a first surface and a second surface opposite of the first surface, and the second die is electrically coupled to a top surface of the leadframe through a plurality of wirebonds. The second surface of the second die is attached to the first surface of the first die.

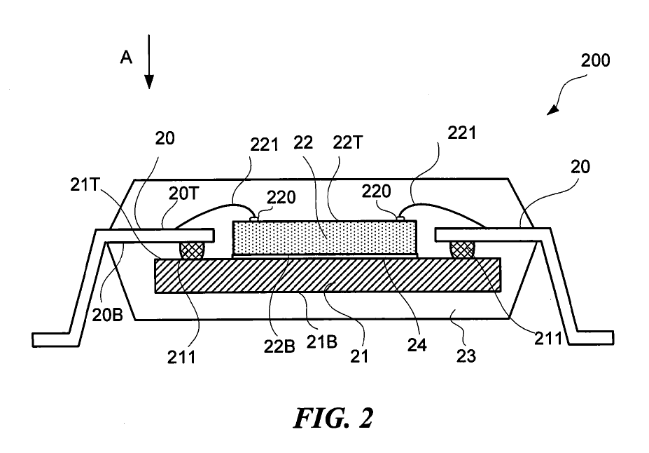

One skilled in the art will understand that several of the details set forth below are provided to describe the following embodiments in a manner sufficient to enable a person skilled in the relevant art to make and use the disclosed embodiments. Several of the details described below, however, may not be necessary to practice certain embodiments of the technology. Additionally, the technology can include other embodiments that are within the scope of the claims but are not described in detail with respect to FIGS. 2-9B.

FIG. 2 is a cross-section view of a stacked die package 200 according to embodiments of the present technology. As shown in FIG. 2, the stacked die package 200 comprises a leadframe 20, a first die 21, a second die 22, flip-chip contact bumps 211 and wirebonds 221. In one embodiment, the first die 21 is a power discrete device, for example, a MOSFET (Metal Oxide Semiconductor Field Effect Transistor) device. And the second die 22 is a controller circuit which is used to control the working of the first die 21. In other embodiments, the package 200 may also include heat sinks and/or other suitable components in addition to or in lieu of the foregoing components of the package 200.

The leadframe 20 comprises a plurality of leads. The first die 21 has a top or first surface 21T proximate to which circuit/circuits and electrical contact pads are formed, and a bottom or second surface 21B opposite the first surface 21T. And the second die 22 has a top or first surface 22T proximate to which circuit/circuits and electrical contact pads are formed, and a bottom or second surface 22B opposite the first surface 22T.

The first die 21 is electrically coupled to the leads at the bottom surface 20B of the leadframe 20 through contact bumps 211 and the second die 22 is electrically coupled to the leads at the top surface 20T of the leadframe 20 through the wirebonds 221. The stacked die package 200 further comprises a molding material 23, encapsulating and protecting the first die 21, the second die 22, contact bumps 211, wirebonds 221 and at least a portion of the leadframe 20. Another portion of the leadframe 20 is exposed outside the molding material 23 to form external pins for communication with external circuitry (not shown). The molding material 23 can include an electrical insulation material such as epoxy and/or other suitable encapsulant.

Continuing with FIG. 2, the first die 21 is a flip-chip die electrically coupled to the leadframe 20 through contact bumps 211 on its top surface 21T. The second die 22 is a wire bonding die electrically coupled to the leadframe 20 through plurality of wirebonds 221. The bottom surface 22B of the wire bonding die 22 is attached to the top surface 21T of the flip-chip die 21. Typically an adhesive 24 is applied between the top surface 21T of the flip-chip die 21 and the bottom surface 22B of the wire bonding die 22. The wire bonding die 22 has a smaller area than the flip-chip die 21 such that the contact pads (not shown) at the periphery of the top surface 21T of the flip-chip die 21 are not covered by the wire bonding die 22.

Contact bumps 211 are positioned on the contact pads of the flip-chip die 21 to function as the input/output nodes of the first die 21 and also are used to connect the first die 21 to the leads of the leadframe 20. Accordingly, die attach paddles are not necessary. Electrical pads 220 are placed on the top surface 22T of the wire bonding die 22 to function as the input/output nodes of the wire bonding die 22. Wirebonds 221 connect the electrical pads 220 of the wire bonding die 22 to the corresponding leads of the leadframe 20.

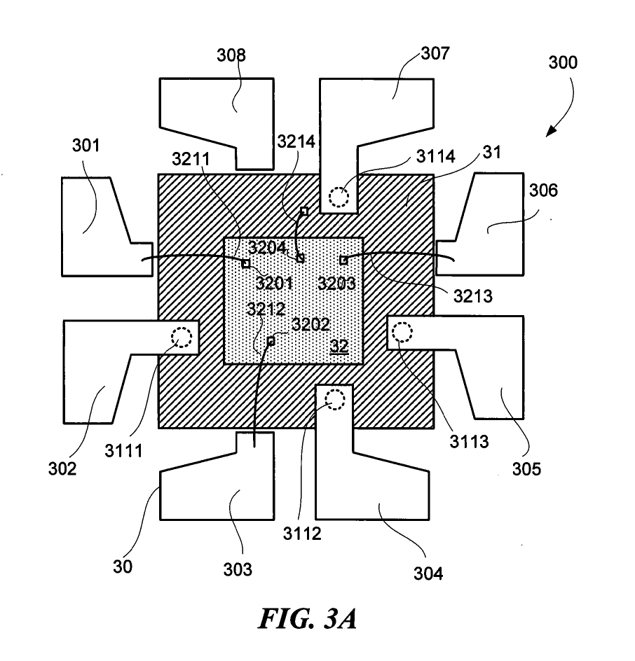

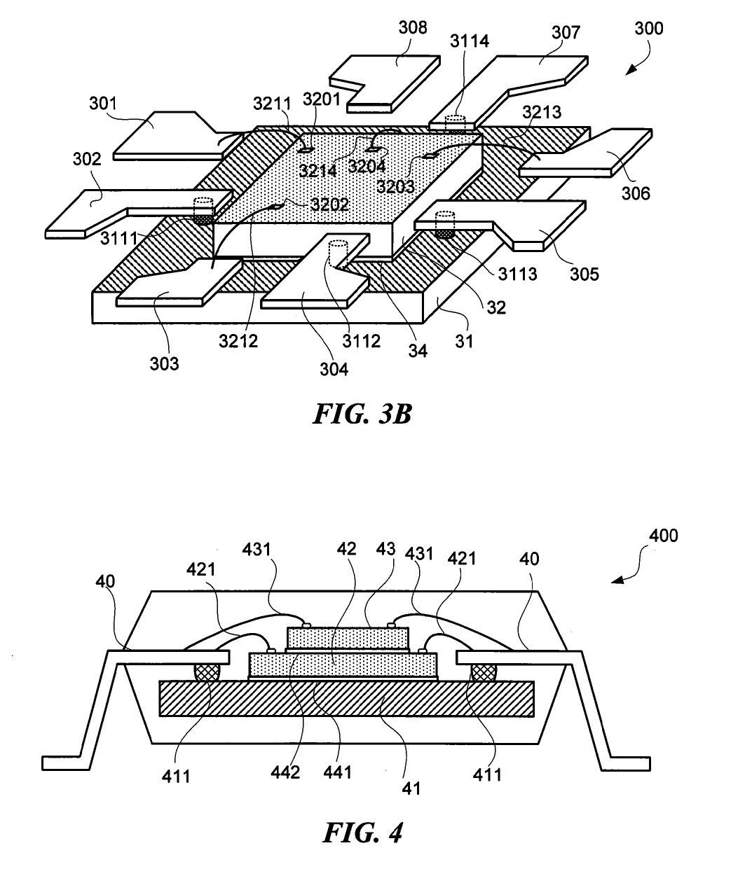

With such a configuration, the leadframe 10 can be overlapped with the first die 21 as seen in FIG. 3A. The bonding sites on the leadframe 20 for receiving the contact bumps 211 are inboard of the edge of the first die 21. This makes the package 200 more compact. Further more, the flip-chip contact bumps 211 have much lower resistance than the wirebonds and the power efficiency for the first die 21 is high, especially for power supply applications.

FIG. 3A is a plan view 300 and FIG. 3B is a perspective view of the stacked die package in FIG. 2. The package 300 comprises a flip-chip die 31, a wire bonding die 32 and a leadframe 30. The wire bonding die 32 is stacked on the flip-chip die 31 via an adhesive 34. The leadframe 30 comprises leads 301-308. The flip-chip die 31 electrically communicates with the leadframe 30 through contact bumps 3111-3114, and the wire bonding die 32 electrically communicates with the leadframe 30 through wirebonds 3211-3214. In order to simplify the description, the molding material 23 is not shown in FIG. 3A and FIG. 3B.

The contact bumps 3111-3114 comprise the first contact bump 3111, the second contact bump 3112, the third contact bump 3113 and the fourth contact bump 3114. The contact bumps 3111-3114 are positioned at the periphery of the flip-chip die 31 and are not covered by the wire bonding die 32. The contact bumps 3111-3114 are placed between the top side surface of the flip-chip die 31 and the bottom side surface of the leadframe 30. Circuit/circuits are fabricated at least proximate to the top surface of the flip-chip die 31.

Contact pads (not shown) are formed on the top surface as the input/output terminals of the flip-chip die 31 and the contact bumps 3111-3114 are formed on the contact pads for connecting the flip-chip die 31 to the leadframe 30. The first contact bump 3111 electrically couples the second lead 302 to the flip-chip die 31. The second contact bump 3112 electrically couples the fourth lead 304 to the flip-chip die 31. The third contact bump 3113 electrically couples the fifth lead 305 to the flip-chip die 31 and the fourth contact bump 3114 electrically couples the seventh lead 307 to the flip-chip die 31 respectively.

Electrical contact pads 3201-3203 are formed on the top side surface of the wire bonding die 32. The first contact pad 3201 is connected to the first lead 301 through the wirebond 3211. The second contact pad 3202 is connected to the third lead 303 with the wirebond 3212. And the third contact pad 3203 is connected to the sixth lead 306 with the wirebond 3213. The eighth lead 308 is floating, i.e., it does not connect to the die 31 or 32 with either contact bump or wirebond. Wirebond 3214 is adopted to directly connect the contact pad 3204 of the wire bonding die 32 to the flip-chip die 31. The position relationship of the leadframe 30, the flip-chip die 31 and the wire bonding die 32 are fixed by the contact bumps 3111-3114 and the wirebonds 3211-3214. The fixed position relationship of the leadframe 30, the flip-chip die 31 and the wire bonding die 32 are further supported and secured by the molding material 23 (FIG. 2).

In certain embodiments, a stacked die package integrating flip-chip die/dies and wire bonding die/dies comprises more than two dies. In one embodiment as shown in FIG. 4, the stacked die package 400 comprises three dies vertically stacked together through the adhesives 441 and 442. One is flip-chip die 41 and two are wire bonding dies 42 and 43. The flip-chip die 41, the first wire bonding die 42 and the second wire bonding die 43 are stacked together sequentially. The second wire bonding die 43 has the smallest area, and the flip-chip die 41 has the largest area such that the input/output terminals on the top side surfaces of all the three dies are exposed. The flip-chip die 41 is connected to the leadframe 40 through contact bumps 411. The wire bonding die 42 is connected to the leadframe 40 through wirebonds 421 and the wire bonding die 43 is connected to the leadframe 40 through wirebonds 431.

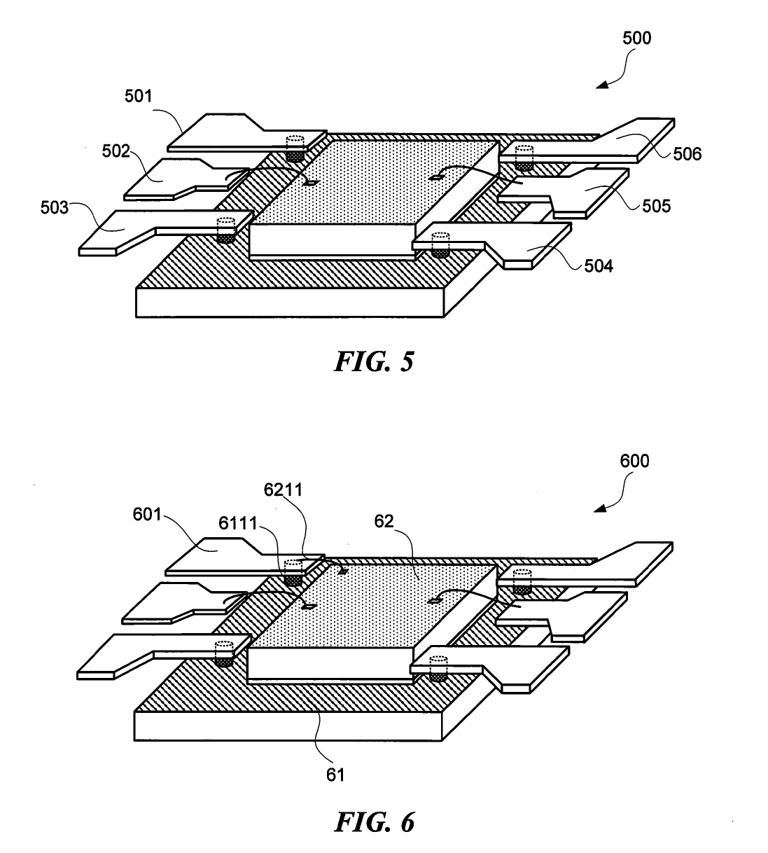

For different applications, the number of contact bumps, wirebonds and leads of the leadframe may vary. For the stacked die package 500 as shown in FIG. 5, the leadframe comprises six leads 501-506 according to one embodiment of the present technology. In some embodiments, some of the leads are floating which are not connected to the die with either contact bump or wirebond. While for other embodiments, none of the leads is floating.

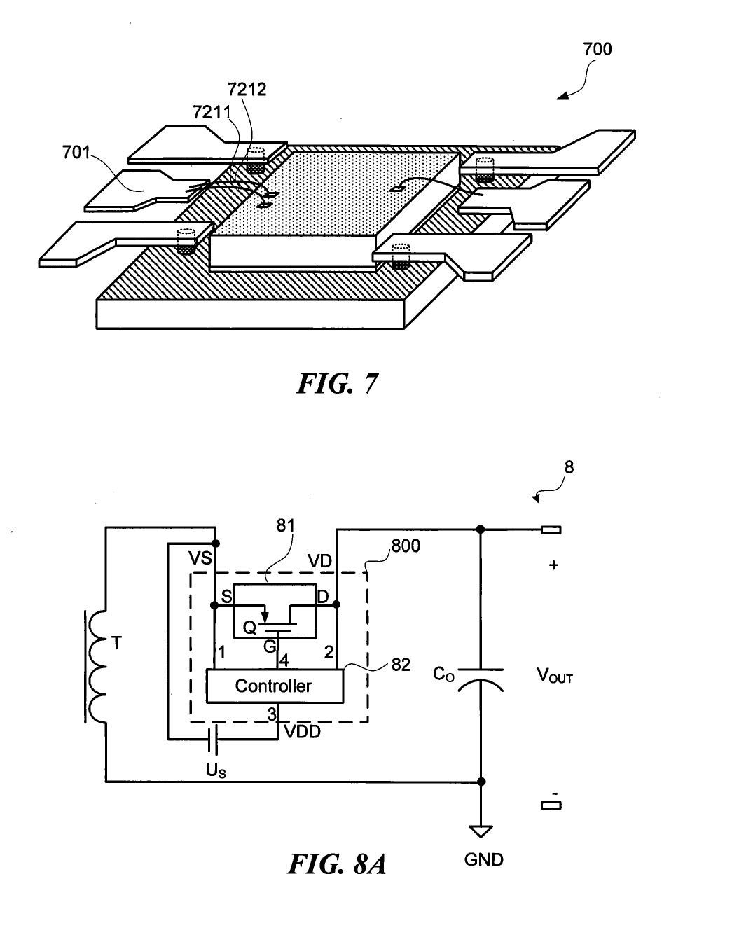

In some embodiments, for one or more leads of the leadframe, each lead is connected both to the flip-chip die and the wire bonding die. Referring to FIG. 6, one embodiment of the stacked die package 600 shows that the lead 601 is connected both to the flip-chip die 61 through the contact bump 6111 and to the wire bonding die 62 through the wirebond 6211. While in other embodiments, more than one wirebonds or contact bumps are connected to one lead. Referring to FIG. 7 as an example, a first wirebond 7211 and a second wirebond 7212 are both connected to the lead 701.

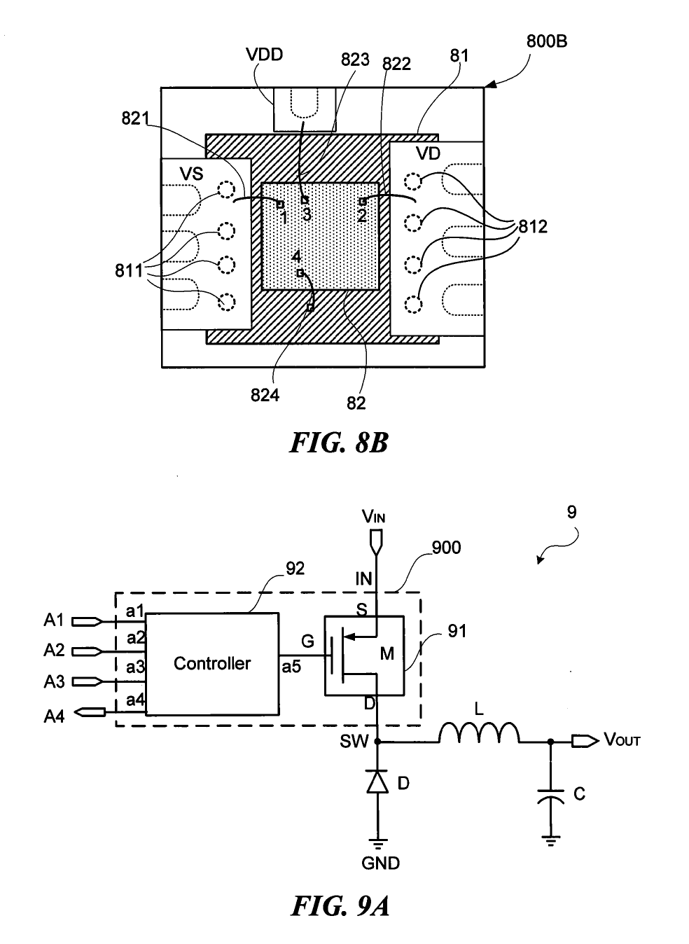

FIGS. 8A-8B show a synchronous rectification module 800 and a corresponding package 800B according to embodiments of the present technology. The synchronous rectification module 800 comprises a synchronous rectifier die 81 and a controller die 82 coupled to drive the rectifier Q according to the source-drain voltage V_{SD} of the rectifier Q.

In one embodiment as shown in FIG. 8A, the synchronous rectification module 800 is adopted as a secondary side synchronous rectifier of a fly-back converter. The synchronous rectification circuit 8 comprises a secondary winding T, the synchronous rectification module 800 and an output filter capacitor C_{O}. One end of the secondary winding T is connected to the secondary ground GND. The other end of the secondary winding T is connected to the first node VS of the synchronous rectification module 800. The package of the synchronous rectification module 800 comprises three leads VS, VD and VDD. The rectifier die 81 has a source S, a gate G and a drain D.

The controller die 82 has a first sensing node 1, a second sensing node 2, a control end 3 and a power supply node 4. The first lead VS is externally connected to the secondary winding T, and internally connected to the source S of the rectifier die 81 and the first sensing node 1 of the controller die 82. The second lead VD is externally connected to the output node OUT of the synchronous rectification circuit 8, and internally connected to the drain D of the rectifier die 81 and the second sensing node 2 of the controller die 82.

In the package 800, the gate G of the rectifier die 81 is connected to the driving node 4 of the controller die 82. Such that the controller die 82 drives the rectifier die 81 according to the differential voltage V_{SD} across the first lead VS and the second lead VD. The third lead VDD is externally connected to a power source US and internally connected to the power supply node 3 of the controller die 82. In the embodiment as shown in FIG. 8A, the rectifier is a MOSFET device. Yet in other embodiments, the rectifier device is other transistor device such as JFET (Junction Field Effect Transistor).

FIG. 8B is a plan view of the package 800B of the synchronous rectification module 800. The package 800B comprises a synchronous rectifier die 81, a controller die 82, the first lead VS, the second lead VD and the third lead VDD. The synchronous rectifier die 81 is electrically coupled to the bottom surface of the leadframe through contact bumps. The contact bumps are shown in dotted circles to indicate they are at the bottom surface of the leadframe. The controller die 82 is electrically coupled to the top surface of the leadframe through wirebonds. And the bottom surface of the controller die 82 is attached on the top surface of the synchronous rectifier die 81.

The leadframe comprises the first lead VS, the second lead VD and the third lead VDD. Specifically, the synchronous rectifier 81 has its source contact pads (not shown, under the contact bumps 811) electrically coupled to the first lead VS through a first contact bumps 811 and has its drain contact pads electrically coupled to the second lead VD through a second contact bumps 812. The controller die 82 has its first sensing node 1 coupled to the first lead VS through a first wirebond 821, has a second sensing node 2 electrically coupled to the second lead VD through a second wirebond 822 and has a power supply node 3 electrically coupled to the third lead VDD through a third wirebond 823. The controller die 82 is electrically coupled to the opposite surface of the leadframe from the flip-chip contact bumps. The driving pad 4 of the controller die 82 is electrically coupled to the gate contact pad of the synchronous rectifier die 81 through a fourth wirebond 824. The package 800B shown in FIG. 8B adopts a leadless format with part of the leads exposed outside the package 800B to form the pins. However, in other embodiments, leaded package formats such as SOP can also be adopted.

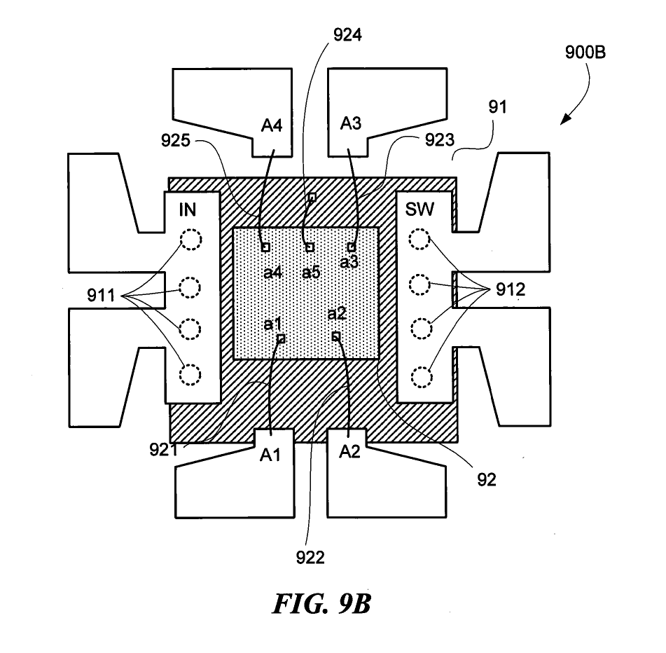

FIGS. 9A and 9B show a converter module 900 and a corresponding package 900B according to embodiments of the present technology. A buck converter 9 is illustrated as an example of the converter module 900. The buck converter 9 further comprises a low side rectifier of diode D, an output inductance L, and an output capacitor C, and the inductance L and the capacitor C are discrete devices exclusive from the converter module 21.

The converter module 900 comprises a switch die 91 on which a switch device is fabricated and a controller die 92 on which control circuits are fabricated, coupled to drive the main switch M in the switch die 91. The switch die 91 has a source, a drain D and a gate G. The controller die has several input/output nodes a1-a4 and a driving node a5.

The package of the converter module 900 comprising multiple leads IN, SW, A1-A4 wherein the first lead IN is externally coupled to receive an input power source V_{IN} and internally connected to the source S of the switch M. The second lead SW is externally coupled to the diode D and to one terminal of the output inductance L, and internally coupled to the drain D of the switch M. The other terminal of the inductance L couples with the output capacitor C and provides the output voltage V_{OUT}. The other end of the diode D is connected to the ground GND. The leads A1-A4 of the converter module 900 are internally coupled to the input/output nodes a1-a4 of the controller die 92. In other embodiment, the leads electrically coupled to the input/output nodes of the controller die 92 are other than four. The driving node a5 of the controller die 92 is electrically coupled to the gate G of the switch die 91 such that the controller die 92 controls the turn-on and turn-off of the switch M. When the switch M is turned on, current flows from the source of the switch M to the node SW, and V_{OUT} increases gradually. When the switch M is turned off, current flows through the rectifier D, and V_{OUT} decreases gradually. V_{OUT} is kept steady by controlling the switching duty cycle of the switch M.

The package 900B as shown in FIG. 9B comprises the switch die 91, the controller die 92 and six leads IN, SW, and A1-A4. The switch die 91 is electrically coupled to the bottom surface of the leadframe through a plurality of contact bumps 911 (shown in dotted circles). The controller die 92 is electrically coupled to the top surface of the leadframe through a plurality of wirebonds. The controller die 92 is attached on the top surface of the flip-chip die 91. The leadframe comprises the first lead IN, the second lead SW and the four third leads A1-A4. Specifically, the source contact pads of the switch die 91 are electrically coupled to the first lead IN through a plurality of first contact bumps 911 and the drain contact pads of the switch die 91 are electrically coupled to the second lead SW through a plurality of second contact bumps 912. The input/output nodes a1-a4 of the controller die 92 are electrically coupled to the third leads A1-A4 through a plurality of fourth wirebonds 921-924 respectively. Also, the gate of the switch die 91 is electrically coupled to the driving node a5 of the controller die 92 through a fifth wirebond 925.

From the foregoing, it will be appreciated that specific embodiments of the technology have been described herein for purposes of illustration, but that various modifications may be made without deviating from the disclosure. Though “lead” or “leads”, “contact bump” or “contact bumps”, “wire” or “wires”, “pad” or “pads” and other similar terms are referred in the description with singular or plural forms, it is not confined to the singular or plural numbers, and any number is considered in the embodiments. Many of the elements of one embodiment may be combined with other embodiments in addition to or in lieu of the elements of the other embodiments. Accordingly, the disclosure is not limited except as by the appended claims.

I/We claim:

1. A stacked die package, comprising:
a leadframe having a plurality of leads;
a first die having a plurality of contact bumps at a first surface and a second surface opposite of the first surface, the first die being electrically coupled to the leadframe through the plurality of contact bumps; and
a second die having a first surface and a second surface opposite of the first surface, the second die being electrically coupled to the leadframe through a plurality of wirebonds, wherein the second surface of the second die is attached to the first surface of the first die.

2. The package of claim 1, wherein the first die is electrically coupled to a bottom surface of the leadframe and the second die is electrically coupled to a top surface of the leadframe.

3. The package of claim 1, further comprising a molding material encapsulating the first die, the second die, the contact bumps, the wirebonds, and at least a portion of the leadframe.

4. The package of claim 1, wherein the second die has a smaller footprint than the first die.

5. The package of claim 1, wherein an adhesive is directly between the first surface of the first die and the second surface of the second die.

6. The package of claim 1, wherein the first die is a power discrete device and the second die is a controller circuit for controlling the power discrete device.

7. The package of claim 6, wherein the power discrete device comprises a MOSFET device.

8. The package of claim 1, further comprises a third die attached on the first surface of the second die, wherein the third die is electrically coupled to the top surface of the leadframe through wirebonds.

9. The package of claim 1, wherein one or more of the leads are floating.

10. A synchronous rectification module, comprising:
a leadframe comprising a first lead, a second lead, and a third lead;
a synchronous rectifier die having a source, a gate, and a drain, wherein the source is electrically coupled to the first lead through a first contact bump, and wherein the drain is electrically coupled to the second lead through a second contact bump; and
a controller die having a first node electrically coupled to the first lead through a first wirebond, having a second node electrically coupled to the second lead through a second wirebond, and having a third node electrically coupled to the third lead through a third wirebond;
wherein the controller die is mounted on a surface of the synchronous rectifier die.

11. The synchronous rectification module of claim 10, wherein the controller die has a driving node electrically coupled to the gate of the synchronous rectifier die through a fourth wirebond.

12. The synchronous rectification module of claim 11, wherein the synchronous rectifier die is electrically coupled to a bottom surface of the leadframe and the controller die is electrically coupled to a top surface of the leadframe.

13. The synchronous rectification module of claim 12, wherein the module functions as a secondary synchronous rectifier of a fly-back converter, and wherein the third lead is externally connected to a power source.

14. A converter module, comprising:
a leadframe having a first lead, a second lead, and a third lead;
a switch die having a gate, a drain, and a source, wherein the source is electrically coupled to the first lead through a plurality of first contact bumps, and the drain is electrically coupled to the second lead through a plurality of second contact bumps; and
a controller die having an input/output node electrically coupled to the third lead through a fourth wirebond, and an output node electrically coupled to the gate of the switch die through a fifth wirebond;
wherein the controller die is attached on a surface of the switch die.

15. The converter module of claim 14, wherein the switch die is electrically coupled to a bottom surface of the leadframe and the controller die is electrically coupled to a top surface of the leadframe.

16. The converter module of claim 14, wherein the switch die includes a high side switch of a buck converter.
